(19) United States
(12) Patent Application Publication
(10) Pub. No.: US 2009/0162550 A1
(43) Pub. Date: Jun. 25, 2009

(54) COPPER (I) AMIDINATES AND GUANIDINATES, MIXED LIGAND COPPER COMPLEXES, AND COMPOSITIONS FOR CHEMICAL VAPOR DEPOSITION, ATOMIC LAYER DEPOSITION, AND RAPID VAPOR DEPOSITION OF COPPER

(75) Inventors: Tianniu Chen, Rocky Hill, CT (US); Chongying Xu, New Milford, CT (US); Thomas H. Baum, New Fairfield, CT (US); Bryan C. Hendrix, Danbury, CT (US); Thomas M. Cameron, Newtown, CT (US); Jeffrey F. Roeder, Brookfield, CT (US); Matthias Stender, New Milford, CT (US)

Correspondence Address: INTELLECTUAL PROPERTY / TECHNOLOGY LAW, PO BOX 14329, RESEARCH TRIANGLE PARK, NC, 27709, US

(73) Assignee: ADVANCED TECHNOLOGY MATERIALS, INC., Danbury, CT (US)

(21) Appl. No.: 12/303,250

(22) PCT Filed: Dec. 29, 2006
(86) PCT No.: PCT/US2006/062709

§ 371 Date: Jan. 13, 2009

Related U.S. Application Data
(60) Provisional application No. 60/810,578, filed on Jun. 2, 2006.

(51) Int. Cl. C23C 16/00; C07F 1/08; C09D 5/00

(52) U.S. Cl. 427/252; 556/35; 106/1.26

(57) ABSTRACT

Copper (I) amidinate and copper (I) guanidinate precursors for forming copper thin films in the manufacture of microelectronic device articles, e.g., using chemical vapor deposition, atomic layer deposition, and rapid vapor deposition processes, as well as mixed ligand copper complexes suitable for such processes. Also described are solvent/additive compositions for copper precursors for CVD/ALD of copper metal films, which are highly advantageous for liquid delivery of such copper amidinates and copper guanidinates, as well as for other organocopper precursor compounds and complexes, e.g., copper isoureate complexes.

### CROSS-REFERENCE TO RELATED APPLICATION

The benefit of priority of U.S. Provisional Patent Application 60/810,578 filed Jun. 2, 2006 is hereby claimed.

### FIELD OF THE INVENTION

The present invention relates to novel copper (I) amidinates and guanidinates and their synthesis, to a method for production of copper circuits in microelectronic device structures using such novel copper precursors and to solvent/additive compositions useful for such copper (I) amidinates and guanidinates, as well as for other copper precursors, in chemical vapor deposition, atomic layer deposition and rapid vapor deposition applications. The invention further relates to mixed ligand copper complexes suitable for such deposition applications. The invention also relates to processes for copper deposition, microelectronic device fabrication, and stabilization of organocopper compounds and complexes.

### DESCRIPTION OF THE RELATED ART

As a result of its low resistivity, low contact resistance, and ability to enhance device performance through the reduction of RC time delays, copper has emerged as a preferred metal for metallization of very large scale integrated (VLSI) devices. Copper metallization has been adopted by many microelectronic device manufacturers for production of microelectronic chips, thin-film recording heads and packaging components.

Chemical vapor deposition (CVD) of copper provides uniform coverage for the metallization. Atomic layer deposition (ALD), which is a modified CVD process, also provides uniform step coverage which is critical for copper seed layers. In ALD an excess amount of precursor is delivered to the deposition chamber for reaction therein to form a monolayer of reacted precursor on the wafer surface. The deposition chamber is purged with a carrier gas to remove unreacted precursor followed by the delivery of a reactant to the deposition chamber for reaction with the monolayer of reacted precursor to form the preferred material. This cycle is repeated until the desired thickness of material is achieved. Advantageously, ALD provides uniform step coverage and a high level of control over film thicknesses and as such is used extensively for the deposition of very thin films, such as diffusion barrier layers and copper seed layers, on wafer surfaces having high aspect ratio trenches and vias.

In an illustrative ALD process, sequential precursor pulses are used to form a film, layer by layer. A first precursor may be introduced to form a gas monolayer on a substrate, followed by introduction of a second precursor to react with the gas monolayer to form a first film layer. Each cycle including first and second precursor pulses therefore forms one monolayer. The process then is repeated to form successive layers until a film of desired thickness is obtained.

Rapid vapor deposition is similar in nature to atomic layer deposition, involving alternate introduction of reactant gases to the substrate but providing faster film formation than ALD.

Liquid precursors and/or solid precursors dissolved in suitable solvents enable the direct injection and/or liquid delivery of precursors into a CVD, ALD or RVD vaporizer unit. The accurate and precise delivery rate can be obtained through volumetric metering to achieve reproducibility during CVD, ALD or RVD metallization of a VLSI device. Solid precursor delivery via specially-designed devices, such as ATMI's ProE Vap (ATMI, Danbury, Conn., USA) enables highly efficient transport of solid precursors to a CVD or ALD reactor.

Fluorine-containing copper CVD precursors have been extensively investigated, for example (hfac)CuL, where hfac=1,1,1,5,5,5-hexafluoroacetylacetonato, and L=neutral Lewis base ligand, which has led to the commercial availability of a number of fluorine-containing copper CVD precursors such as (hfac)Cu(MHY), (hfac)Cu(3-hexyne), (hfac)Cu(DMCOD) and (hfac)Cu(VTMS), wherein MHY=2-methyl-1-hexen-3-yne, DMCOD=dimethylcyclooctadiene, and VTMS=vinyltrimethylsilane.

Copper metallization in integrated circuit manufacture typically utilizes a barrier layer between the copper layer and the underlying structure in order to prevent detrimental effects that may be caused by the interaction of a copper layer with other portions of the integrated circuit. A wide range of barrier materials is conventionally utilized, including materials comprising metals, metal nitrides, metal silicides, and metal silicon nitrides. Exemplary barrier materials include titanium nitride, titanium silicide, tantalum nitride, tantalum silicide, tantalum silicon nitrides, niobium nitrides, niobium silicon nitrides, tungsten nitride, and tungsten silicide. In instances where (hfac)CuL type precursors are used for copper metallization, interfacial layers are formed between the barrier layer and the copper layer, which cause the metallization to have poor adhesion and high contact resistivity.

The deficiencies of inferior adhesion and excessively high contact resistivity incident to formation of fluorine-containing interfacial layers when using (hfac)CuL copper precursors has been attributed to the fluorine-containing hfac ligand. To overcome such deficiencies, it would be a significant advance in the art to provide novel fluorine-free copper precursors, which upon deposition display superior adhesion and low contact resistivity.

Recently, amidinate and guanidinate anions have received some attention for use as ligands in coordination and organometallic compounds, specifically because of the ease of substitution at the carbon and nitrogen atoms and the associated versatility and flexibility that is provided. The properties of complexes including amidinate and guanidinate ligands are readily adjusted by varying the steric demands of such ligands.

It would therefore be advantageous to provide new copper (I) amidinate and guanidinate precursors and formulations having utility for CVD and ALD, as well as methods of depositing copper in the manufacturing of integrated circuits and other microelectronic device structures using such precursors and formulations.

It would also be advantageous to provide suitable solvent compositions for such precursors to enable their use in liquid delivery copper deposition processes such as CVD and ALD in a highly efficient manner.

### SUMMARY OF THE INVENTION

The present invention relates generally to copper (I) amidinate and copper (I) guanidinate compounds useful as source reagents for forming copper on substrates, and to methods of depositing copper thin films using such copper (I) amidinate and/or copper (I) guanidinate compounds, as well as liquid delivery compositions, and methods for depositing copper on substrates, manufacturing microelectronic devices, and stabilizing organocopper compounds and complexes.

The present invention in one aspect relates to a copper precursor compound selected from those of the formulae:

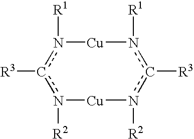

wherein:

R¹, R², and R³ may be the same as or different from one another and each is independently selected from the group consisting of H, linear or branched C₁-C₆ alky, C₁-C₆ alkoxy, C₁-C₆ alkylamino, C₂-C₆ alkenyl, C₆-C₁₀ aryl, C₁-C₆ silyl and C₆-C₁₀ aryloxy groups, with the provision that at least one of R¹, R², and R³ is a C₁-C₆ alkoxy or a C₆-C₁₀ aryloxy group; and

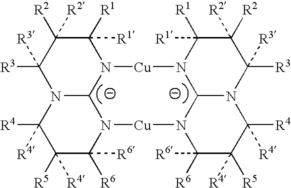

wherein:

R¹, R^{1′}, R², R^{2′}, R³, R^{3′}, R⁴, R^{4′}, R⁵, R^{5′} and R⁶, R^{6′} may be the same as or different from one another and each is independently selected from the group consisting of H, linear or branched C₁-C₆ alkyl, C₁-C₆ alkoxy, C₁-C₆ alkylamino, C₂-C₆ alkenyl, and C₁-C₆ silyl groups, with the provision that each of R¹-R⁶ cannot be H at the same time.

In yet another aspect, the present invention relates to a copper precursor formulation, comprising:

(a) a copper precursor compound of the formula selected from the group consisting of:

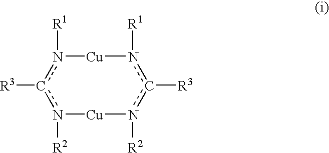

wherein:

R¹, R², and R³ may be the same as or different from one another and each is independently selected from the group consisting of H, linear or branched C₁-C₆ alkyl, C₁-C₆ alkoxy, C₁-C₆ alkylamino, C₂-C₆ alkenyl, C₆-C₁₀ aryl, C₁-C₆ silyl and C₆-C₁₀ aryloxy groups, with the provision that at least one of R¹, R², and R³ is a C₁-C₆ alkoxy or a C₆-C₁₀ aryloxy group; and

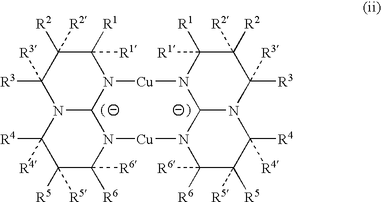

wherein:

R¹, R^{1′}, R², R^{2′}, R³, R^{3′}, R⁴, R^{4′}, R⁵, R^{5′} and R⁶, R^{6′} may be the same as or different from one another and each is independently selected from the group consisting of H, linear or branched C₁-C₆ alkyl, C₁-C₆ alkoxy, C₁-C₆ alkylamino, C₂-C₆ alkenyl, and C₁-C₆ silyl groups, with the provision that each of R¹-R⁶ cannot be H at the same time; and

(b) at least one organic solvent for the precursor compound.

In a still further aspect, the compounds of the invention may be used in a method of depositing copper on a microelectronic device, comprising:

(a) volatilizing a copper precursor of the formula selected from the group consisting of:

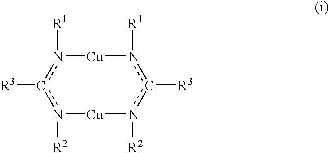

wherein:

R¹, R², and R³ may be the same as or different from one another and each is independently selected from the group consisting of H, linear or branched C₁-C₆ alkyl, C₁-C₆ alkoxy, C₁-C₆ alkylamino, C₂-C₆ alkenyl, C₆-C₁o aryl, C₁-C₆ silyl and C₆-C₁₀ aryloxy groups, with the provision that at least one of R¹, R², and R³ is a C₁-C₆ alkoxy or a C₆-C₁₀ aryloxy group; and

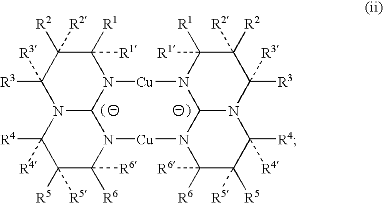

wherein:

R¹, R^{1′}, R², R^{2′}, R³, R^{3′}, R⁴, R^{4′}, R⁵, R^{5′} and R⁶, R^{6′} may be the same as or different from one another and each is independently selected from the group consisting of H, linear or branched C₁-C₆ alkyl, C₁-C₆ alkoxy, C₁-C₆ alkylamino, C₂-C₆ alkenyl, and C₁-C₆ silyl groups, with the provision that each of R¹-R⁶ cannot be H at the same time; and

(b) contacting the precursor vapor with the microelectronic device under elevated temperature vapor decomposition conditions to deposit copper on the microelectronic device.

The compounds of the invention can be used for a method of depositing copper on a microelectronic device, comprising:

(a) volatilizing a copper precursor formulation comprising:
(i) a copper precursor compound of the formula selected from the group consisting of:

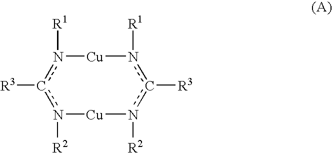

wherein:

R¹, R², and R³ may be the same as or different from one another and each is independently selected from the group consisting of H, linear or branched C₁-C₆ alkyl, C₁-C₆ alkoxy, C₁-C₆ alkylamino, C₂-C₆ alkenyl, C₆-C₁₀ aryl, C₁-C₆ silyl and C₆-C₁₀ aryloxy groups, with the provision that at least one of R¹, R², and R³ is a C₁-C₆ alkoxy or a C₆-C₁₀ aryloxy group; and

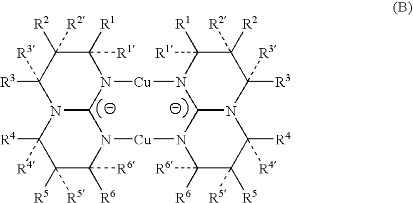

wherein:

R¹, R^{1′}, R², R^{2′}, R³, R^{3′}, R⁴, R^{4′}, R⁵, R^{5′} and R⁶, R^{6′} may be the same as or different from one another and each is independently selected from the group consisting of H, linear or branched C₁-C₆ alkyl, C₁-C₆ alkoxy, C₁-C₆ alkylamino, C₂-C₆ alkenyl, and C₁-C₆ silyl groups, with the provision that each of R¹-R⁶ cannot be H at the same time; and
(ii) at least one organic solvent for the precursor compound,

to form a precursor vapor; and

(b) contacting the precursor vapor with the microelectronic device under elevated temperature vapor decomposition conditions to deposit copper on the microelectronic device.

A still further aspect of the invention relates to a method of making the copper precursor compounds according to the methods described herein.

The compounds of the invention enable improved microelectronic devices, and products incorporating same, to be manufactured by methods comprising depositing copper on a microelectronic device, using the methods and/or compositions described herein.

A further aspect of the invention relates to a precursor vapor comprising vapor of a copper precursor compound of the present invention.

A still further aspect of the invention relates to a precursor storage and dispensing package, containing a copper precursor of the present invention.

As used herein, the designation of organo substituents by reference to carbon numbers, includes ranges as well as sub-ranges within the ranges identified by end-point carbon numbers, and such sub-ranges may be specified, e.g., as including one of such end-point carbon numbers in such a sub-range, or as including carbon numbers greater than the lower end-point carbon number and less than the upper end-point carbon number of the range, to constitute various sub-ranges in the various specific embodiments of the invention. Alkyl groups may be branched or unbranched.

A further aspect of the invention relates to a copper precursor composition, comprising (i) an organocopper compound or complex, and (ii) one of isoureas of formula (A) and guanidines of formula (B):

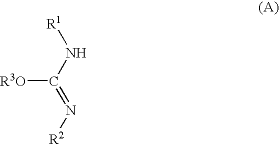

wherein each of R¹, R² and R³ is independently selected from hydrogen, C₁-C₈ alkyl, C₂-C₈ alkenyl, amino, aryls, C₁-C₆ alkylamino, silyl, mono-, bi- and tri-alkylsilyl wherein alkyl is C₁-C₈ alkyl, and cyano (—CN); and

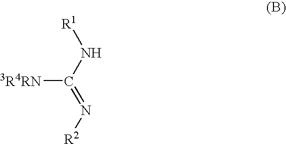

wherein each of R¹, R², R³ and R⁴ is independently selected from hydrogen, C₁-C₈ alkyl, C₂-C₈ alkenyl, amino, aryls, C₁-C₆ alkylamino, silyl, mono-, bi- and tri-alkylsilyl wherein alkyl is C₁-C₈ alkyl, and cyano (—CN).

In a further aspect, the invention relates to a copper precursor composition comprising N,N-dimethyl-N′,N″-diisopropylguandine (i.e., HDMAPA) and CuDMAPA.

Another aspect of the invention relates to a copper precursor composition comprising o-methyl-N,N′-diisopropylisourea (i.e., HMOPA) and CuMOPA.

A still further aspect of the invention relates to a copper precursor composition, selected from the group consisting of:

(a) CuMOPA in HMOPA solution; and

(b) CuDMAPA in HDMAPA solution.

Yet another aspect of the invention relates to a method of depositing copper on a substrate, comprising contacting the substrate with a vapor of a copper precursor composition as described above.

In a further aspect, the invention relates to a method of fabricating a microelectronic device, comprising use of a copper precursor composition as above described.

Still another aspect of the invention relates to a method of stabilizing a copper complex against degradation at elevated temperature, wherein the copper complex is selected from the group consisting of copper amidinates, copper guanidinates, and copper isoureates, such method comprising formulating said copper complex with a corresponding amidine, guanidine or isourea compound.

A further aspect of the invention relates to a method of stabilizing a copper complex against degradation at elevated temperature, wherein the copper complex is selected from the group consisting of copper amidinates, copper guanidinates, and copper isoureates, such method comprising formulating the copper complex with HMOPA or HDMAPA.

The invention in a further aspect relates to mixed ligand copper complexes suitable for use in CVD, ALD and RVD applications. Such mixed ligand copper complexes have the general formula:

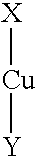

wherein X and Y are each monoanionic and selected from the parent ligands (A)-(H) below, with the proviso that X and Y are different from one another:

(A) Triazacyclononane-Amide (tacn) Ligands of the Formula

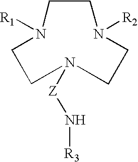

wherein: Z is (CH₂)₂ or SiMe₂; and R₁, R₂ and R₃ are the same as or different from one another, and each is independently selected from among C₁-C₅ alkyl, C₆-C₁₀ aryl, and C₃-C₆ cycloalkyl;

(B) Aminotroponimine Ligands of the Formula

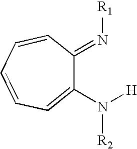

wherein R₁, R₂ are the same as or different from one another and each is independently selected from among H, C₁-C₅ alkyl, C₆-C₁₀ aryl, and C₃-C₆ cycloalkyl;

(C) Bis(Oxazole) Ligands of the Formula

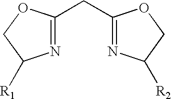

wherein R₁, R₂ are the same as or different from one another and each is independently selected from among H, C₁-C₅ alkyl, C₆-C₁₀ aryl, and C₃-C₆ cycloalkyl;

(D) Guanidine Ligands of the Formula

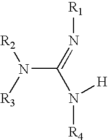

wherein R₁, R₂, R₃, R₄ are the same as or different from one another and are independently selected from among H, C₁-C₅ alkyl, C₆-C₁₀ aryl, and C₃-C₆ cycloalkyl;

(E) Amidine Ligands of the Formula

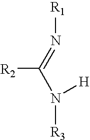

wherein R₁, R₂, R₃ are the same as or different from one another and are independently selected from among H, C₁-C₅ alkyl, C₆-C₁₀ aryl, and C₃-C₆ cycloalkyl;

(F) Cyclopentadiene Ligands of the Formula

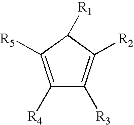

wherein R₁, R₂, R₃, R₄, R₅ are the same as or different from one another and are independently selected from among H, C₁-C₆ alkyl, C₆-C₁₀ aryl, C₁-C₈ alkoxy, C₁-C₈ alkylsilyl, or pendant ligands with additional functional group(s), which can provide further coordination to the metal center, e.g., —CH₂—CH₂—N(CH₃)₂;

(G) Betadiketimine Ligands of the Formula

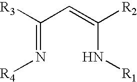

wherein R₁, R₂, R₃, R₄ are the same as or different from one another and are independently selected from among C₁-C₆ alkyl, C₆-C₁₀ aryl, silyl and C₁-C₈ alkylamine; and

(H) Amine Ligands of the Formula

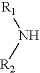

wherein R₁, R₂ are the same as or different from one another and are independently selected from among C₁-C₅ alkyl, C₆-C₁₀ aryl, and C₃-C₆ cycloalkyl.

Other aspects, features and embodiments of the invention will be more fully apparent from the ensuing disclosure and appended claims.

### BRIEF DESCRIPTION OF THE DRAWINGS

FIG. 1 is a ¹H-NMR plot for copper (I) 2-methoxy-1,3-diisopropylamidinate (i.e., CuMOPA).

FIG. 2 is a simultaneous thermal analysis (STA) plot for copper (I) 2-methoxy-1,3-diisopropylamidinate (i.e., CuMOPA).

FIG. 3 is an ORTEP structure showing 30% probability thermal ellipsoids for CuMOPA.

FIG. 4 is simultaneous thermal analysis (STA) plot for copper (I) 2-ethoxy-1,3-diisopropylanidinate.

FIG. 5 is a thermographic analysis (TGA) plot for copper (I) 2-t-butoxy-1,3-diisopropylamidinate.

FIG. 6 illustrates isothermal experiments at 120° C. using copper (I) 2-methoxy-1,3-diisopropylamidinate (CuMOPA), copper (I) 2-dimethylamino-1,3-diisopropylamidinate (CuDMAPA), and copper (II) dimethylaminoethoxide (CuDMAEO).

### DETAILED DESCRIPTION OF THE INVENTION AND PREFERRED EMBODIMENTS THEREOF

The present invention relates to copper (I) amidinate and copper (I) guanidinate precursors and compositions thereof, suitable for use in processes for depositing thin copper films on microelectronic device substrates.

In one aspect, the invention provides a compound of the formula:

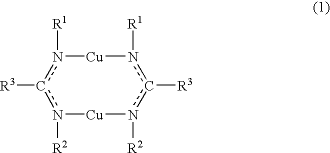

wherein:

R¹, R² and R³ may be the same as or different from one another and each is independently selected from the group consisting of H, linear or branched C₁-C₆ alky, C₁-C₆ alkoxy, C₁-C₆ alkylamino, C₂-C₆ alkenyl, C₆-C₁₀ aryl, C₁-C₆ silyl, C₆-C₁₀ aryloxy and boride groups, with the provision that at least one of R¹, R², and R³ is a C₁-C₆ alkoxy or a C₆-C₁₀ aryloxy group.

Preferred compounds of formula (1) include copper (I) 2-methoxy-1,3-diisopropylamidinate (CuMOPA):

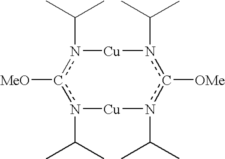

copper (I) 2-ethoxy-1,3-diisopropylamidinate:

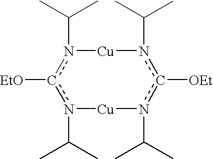

and copper (I) 2-t-butoxy-1,3-diisopropylamidinate:

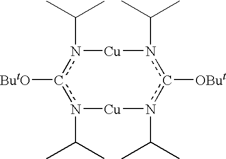

In another aspect, the invention provides copper (I) guanidinate compounds of formula (2):

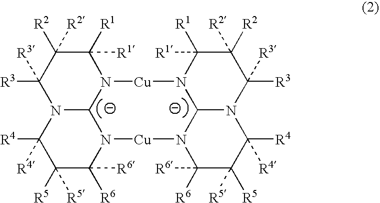

wherein:

R¹, R^{1′}, R², R^{2′}, R³, R^{3′}, R⁴, R^{4′}, R⁵, R^{5′} and R⁶, R^{6′} may be the same as or different from one another and each is independently selected from the group consisting of H, linear or branched C₁-C₆ alkyl, C₁-C₆ alkoxy, C₁-C₆ alkylamino, C₂-C₆ alkenyl, and C₁-C₆ silyl groups, with the provision that each of R¹-R⁶ cannot be H at the same time.

With regards to the method of use and formulations comprising the compound and a solvent, as described hereinbelow, each of R¹-R⁶ may be hydrogen, without limitation. When R¹-R⁶ include alkyl and/or alkoxy functionality, the alkyl and alkoxy substituents may be of any suitable type, e.g., with carbon numbers of C₁-C₄ or with higher carbon numbers such as C₅ and C₆.

In another embodiment, compounds of formula (1) may be readily synthesized according to the following equations (3) and (4):

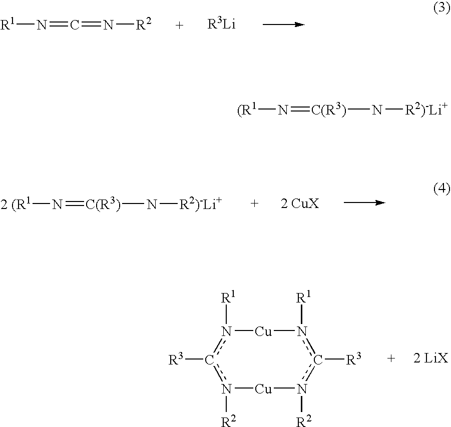

where R¹, R² and R³ are defined hereinabove and X is a halogen. Notably, other alkali metals, such as sodium or potassium, may be used in place of lithium.

In yet another embodiment, compounds of formula (2) may be readily synthesized according to tle following equations (5) and (6):

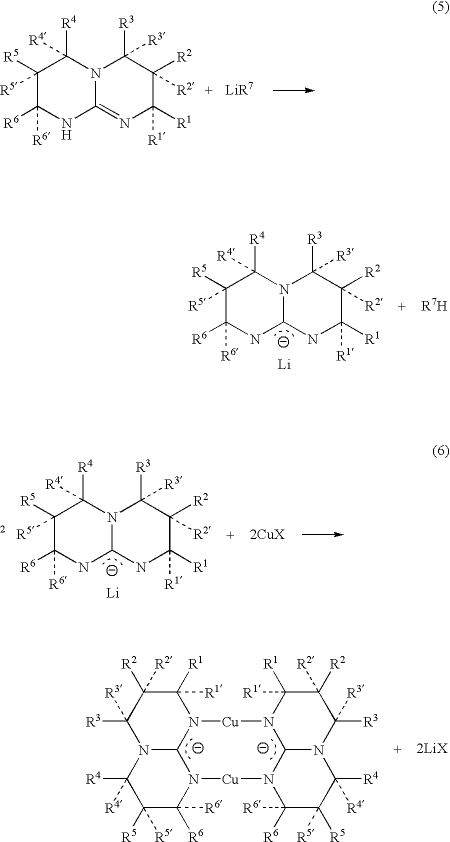

where R¹, R² and R³ are defined hereinabove and X is a halogen. Notably, other alkali metals, such as sodium or potassium, may be used in place of lithium.

The compounds of formulas (1) and (2) are usefully employed for forming copper thin films by CVD or ALD processes, utilizing process conditions, including appertaining temperatures, pressures, concentrations, flow rates and CVD or ALD techniques, as readily determinable within the skill of the art for a given application.

In CVD or ALD usage, the copper (I) precursors of the invention are volatilized to form a precursor vapor that is then contacted with a microelectronic device substrate under elevated temperature vapor decomposition conditions to deposit copper on the substrate.

Preferably, the copper (I) precursors deposited according to the present invention include copper (I) 2-methoxy-1,3-diisopropylamidinate, copper (I) 2-ethoxy-1,3-diisopropylamidinate, copper (I) 2-t-butoxy-1,3-diisopropylamidinate, and copper (I) 1,3,4,6,7,8-hexahydro-2H-pyrimido[1,2-a]pyrimidinate (Cu₂(hpp)₂).

ALD involves the deposition of successive monolayer over a substrate within a deposition chamber typically maintained at subatmospheric pressure. An exemplary method includes feeding a single vaporized precursor into a deposition chamber to form a first monolayer over a substrate positioned therein. The substrate is heated to a temperature that is high enough to prevent condensation of the precursor but low enough to prevent thermal decomposition of said precursor. Thereafter, the flow of the first deposition precursor is ceased and an inert purge gas, e.g., nitrogen or argon, is flowed through the chamber to exhaust any unreacted first precursor from the chamber. Subsequently, a second vaporized precursor the same as or different from the first is flowed into the chamber to form a second monolayer upon the first monolayer. The second monolayer might react with the first monolayer. Additional precursors can form successive monolayer, or the above process can be repeated until a desired thickness and composition layer has been formed over the substrate.

CVD involves the contacting of a volatile metal-organic compound in the gas phase with areas of a substrate where growth of a metal film (e.g., to form an interconnect) is required. A surface catalyzed chemical reaction, e.g., thermal decomposition, occurs and produces deposition of the desired metal. Since the metal film steadily grows on the desired surface, it is of a uniform thickness and highly conformal even to severe (e.g., high aspect) geometries. CVD is well suited to use in fabricating submicron high aspect ratio features.

Copper (I) 2-methoxy-1,3-diisopropylamidinate, copper (I) 2-ethoxy-1,3-diisopropylamidinate, copper (I) 2-t-butoxy-1,3-diisopropylamidinate and Cu₂(hpp)₂ are all volatile and thermally stable, and are usefully employed as solid copper CVD or ALD precursors under reducing pressure deposition conditions in the CVD or ALD reactor. Alternatively, the solid precursors can be dissolved in organic solvents, and liquid delivery processes can be used to meter the solution into a vaporizer for transport of the vapor to the reactor.

The copper (I) amidinate and copper(I) guanidinate precursor compositions of the present invention may be used to form copper interconnect lines in microelectronic device integrated circuitry, thin-film circuitry, thin-film packaging components and thin-film recording head coils. To fabricate such integrated circuitry or thin-film circuitry, a microelectronic device substrate may be utilized having a number of dielectric and conductive layers (multilayers) formed on and/or within the substrate. The microelectronic device substrate may include a bare substrate or any number of constituent layers formed on a bare substrate. As defined herein, “microelectronic device” corresponds to semiconductor substrates, flat panel displays, and microelectromechanical systems (MEMS).

In the broad practice of the present invention, a copper-containing layer may be formed on a microelectronic device substrate using the copper (I) amidinate or copper (I) guanidinate precursor, for use in a first, second, third, or more metallization layer. Such copper layers typically are used in circuit locations requiring low resistivity, high performance and/or high speed circuit paths. As discussed in the background section hereof, a barrier layer may be deposited or otherwise formed on the microelectronic device substrate before a copper layer is formed on said substrate.

Using the copper precursor compositions described herein, copper may then be deposited on the wafer using a CVD or ALD system, such systems being well known in the microelectronic device fabrication art. Further, water, water-generating compounds, or other adjuvant to the precursor formulation may be mixed with the copper precursor upstream of, at, or within, the CVD or ALD tool. Reducing agents may be utilized in an analogous fashion.

As a further variation, when copper alloy compositions are to be deposited on the substrate, the copper precursor formulation may contain or be mixed with other metal source reagent materials, or such other reagent materials may be separately vaporized and introduced to the deposition chamber.

The compositions of the present invention may be delivered to a CVD or ALD reactor in a variety of ways. For example, a liquid delivery system may be utilized. Alternatively, a combined liquid delivery and flash vaporization process unit may be employed, such as the LDS300 liquid delivery and vaporizer unit (commercially available from ATMI, Inc., Danbury, Conn., USA), to enable low volatility materials to be volumetrically delivered, leading to reproducible transport and deposition without thermal decomposition of the precursor. Both of these considerations of reproducible transport and deposition without thermal decomposition are essential for providing a commercially acceptable copper CVD or ALD process.

In liquid delivery formulations, copper precursors that are liquids may be used in neat liquid form, or liquid or solid copper precursors may be employed in solvent formulations containing same. Thus, copper precursor formulations of the invention may include solvent component(s) of suitable character as may be desirable and advantageous in a given end use application to form copper on a substrate.

Suitable solvents may for example include alkane solvents (e.g., hexane, heptane, octane, and pentane), aryl solvents (e.g., benzene or toluene), amines (e.g., triethylamine, tert-butylamine), imines and carbodiimides (e.g., N,N′-diisopropylcarbodiimide), alcohols, ethers, ketones, aldehydes, amadines, guanadines, isoureas, and the like. The utility of specific solvent compositions for particular copper precursors may be readily empirically determined, to select an appropriate single component or multiple component solvent medium for the liquid delivery vaporization and transport of the specific copper precursor that is employed.

In another aspect, the invention provides solvent/additive compositions for copper precursors for CVD/ALD of copper metal films, which are highly advantageous for liquid delivery of the above-described copper amidinates and copper guanidinates of the invention, as well as other organocopper precursor compounds and complexes, e.g., copper isoureate complexes.

The solvent/additive compositions useful for such purpose include isourea and guanidine solvent/additive compositions.

Isourea solvent/additive compositions of the invention include an isourea compound of the formula

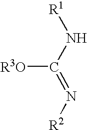

wherein each of R¹, R² and R³ is independently selected from hydrogen, C₁-C₈ alkyl (e.g., methyl, ethyl, propyl, butyl, pentyl, hexyl, heptyl or octy), C₂-C₈ alkenyl, amino, aryls, C₁-C₆ alkylamino, silyl, mono-, bi- and tri-alkylsilyl wherein alkyl is C₁-C₈ alkyl, and cyano (—CN).

Guanidine solvent/additive compositions of the invention include a guanidine compound of the formula

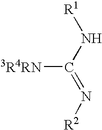

wherein each of wherein each of R¹, R², R³ and R⁴ is independently selected from hydrogen, C₁-C₈ alkyl (e.g., methyl, ethyl, propyl, butyl, pentyl, hexyl, heptyl or octy), C₂-C₈ alkenyl, amino, aryls, C₁-C₆ alkylamino, silyl, mono-, bi- and tri-alkylsilyl wherein alkyl is C₁-C₈ alkyl, and cyano (—CN).

The isourea and guanidine solvent/additive compositions of the invention are usefully employed as solvent/additive compositions for precursors such as the amidinate, guanidinate and isoureate complexes of the following formulae:

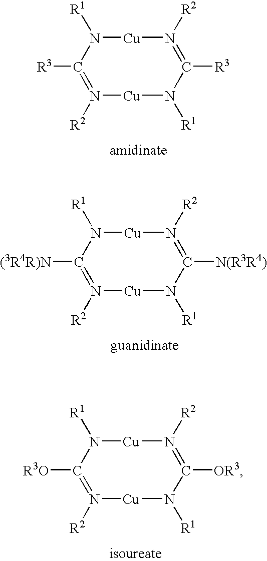

wherein each of R¹, R², R³ and R⁴ is independently selected from hydrogen, C₁-C₈ alkyl (e.g., methyl, ethyl, propyl, butyl, pentyl, hexyl, heptyl or octy), C₂-C₈ alkenyl, amino, C₁-C₆ alkylamino, aryl, silyl, mono-, bi- and tri-alkylsilyl wherein alkyl is C₁-C₈ alkyl, and cyano (—CN).

A preferred isourea solvent/additive is o-methyl-N,N′-diisopropylisourea (HMOPA), which is a starting material for the corresponding isoureate copper complex CuMOPA.

A preferred guanidine solvent/additive is N,N-dimethyl-N′N″-diisopropylguanidine (HDMAPA), which is a starting material for the corresponding guanidinate copper complex CuDMAPA.

We have found that HMOPA prevents disproportionation reaction of CuMOPA in toluene solution at 110° C., and that HDMAPA prevents disproportionation reaction of CuDMAPA in toluene solution at 110° C.

The isourea and guanidine solvent/additive compositions of the invention therefore achieve a significant advance, in providing useful solvent/additive media for copper amidinate, copper guanidinate, and copper isoureate complexes, which overcome stability/solubility issues that would otherwise limit the use of such copper precursor complexes. As a result, the isourea and guanidine solvent/additive compositions of the invention facilitate liquid delivery of copper amidinate, copper guanidinate, and copper isoureate complexes and enhance their stability during use in CVD and ALD copper deposition processes.

Thus, amidine, guanidine or isourea compounds with matching ligands function as solvent/stabilizer species in formulations with corresponding copper precursor complexes to achieve remarkable levels of stabilization of the corresponding copper precursor complex against degradation and precipitation, even after long-term exposure to high temperature.

Any suitable amount of the amidine, guanidine or isourea solvent/stabilizer in such copper precursor complex formulations may be employed for such purpose, to provide extended shelf life of the copper precursor complex. In various embodiments, the amount of such solvent/stabilizer can range from 0.01% to 100% by weight, based on the weight of the copper precursor complex. Specific implementations of such formulation technology of the invention may utilize the amidine, guanidine or isourea solvent/stabilizer at a concentration of 1% by weight, based on the weight of the copper precursor complex to provide enhanced resistance of the copper precursor complex to degradation.

The invention in a further aspect relates to mixed ligand copper complexes suitable for use in CVD, ALD and RVD applications. Such mixed ligand copper complexes have the general formula:

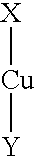

wherein X and Y are each monoanionic and selected from the parent ligands (A)-(H) below, with the proviso that X and Y are different from one another:

(A) Triazacyclononane-Amide (tacn) Ligands of the Formula

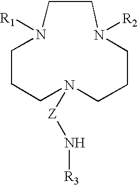

wherein: Z is (CH₂)₂ or SiMe₂; and R₁, R₂ and R₃ are the same as or different from one another, and each is independently selected from among C₁-C₅ alkyl, C₆-C₁₀ aryl, and C₃-C₆ cycloalkyl;

(B) Aminotroponimine Ligands of the Formula

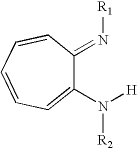

wherein R₁, R₂ are the same as or different from one another and each is independently selected from among H, C₁-C₅ alkyl, C₆-C₁₀ aryl, and C₃-C₆ cycloalkyl;

(C) Bis(Oxazole) Ligands of the Formula

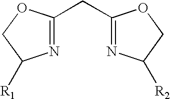

wherein R₁, R₂ are the same as or different from one another and each is independently selected from among H, C₁-C₅ alkyl, C₆-C₁₀ aryl, and C₃-C₆ cycloalkyl;

(D) Guanidine Ligands of the Formula

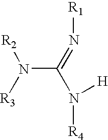

wherein R₁, R₂, R₃, R₄ are the same as or different from one another and are independently selected from among H, C₁-C₅ alkyl, C₆-C₁₀ aryl, and C₃-C₆ cycloalkyl;

(E) Amidine Ligands of the Formula

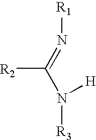

wherein R₁, R₂, R₃ are the same as or different from one another and are independently selected from among H, C₁-C₅ alkyl, C₆-C₁₀ aryl, and C₃-C₆ cycloalkyl;

(F) Cyclopentadiene Ligands of the Formula

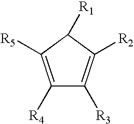

wherein R₁, R₂, R₃, R₄, R₅ are the same as or different from one another and are independently selected from among H, C₁-C₆ alkyl, C₆-C₁₀ aryl, C₁-C₈ alkoxy, C₁-C₈ alkylsilyl, or pendant ligands with additional functional group(s), which can provide further coordination to the metal center, e.g., —CH₂—CH₂—N(CH₃)₂;

(G) Betadiketimine Ligands of the Formula

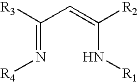

wherein R₁, R₂, R₃, R₄ are the same as or different from one another and are independently selected from among C₁-C₆ alkyl, C₆-C₁₀ aryl, silyl and C₁-C₈ alkylamine; and

(H) Amine Ligands of the Formula

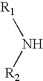

wherein R₁, R₂ are the same as or different from one another and are independently selected from among C₁-C₅ alkyl, C₆-C₁₀ aryl, and C₃-C₆ cycloalkyl.

The foregoing mixed ligand copper complexes are usefully employed for deposition of conformal copper or copper-containing films using CVD/ALD/RVD techniques, as monomeric copper precursors that are transportable (volatile) at temperatures specific to such processes. This aspect of the invention utilizes sterically demanding ligands to generate mixed-ligand, monomeric copper complexes suitable for CVD/ALD/RVD, in which the ligands are selected from tacn (A), aminotroponimines (B), bis-oxazolines (C), guanidines (D), amidines (E), cyclopentadienes (F), beta-diketimines (G), and amines (H). Such ligands will exist in their monoanionic form once associated with the metal. The sterically demanding ligands are selected to force monomeric structures enabling compound transportation at low temperatures.

The mixed ligand complexes of the invention can be readily synthesized from the parent ligands and the metal, wherein each of the two coordinated ligands is different from one another in the complex. Such mixed ligand complexes can be utilized as reagents for copper deposition in CVD, ALD or RVD processes conducted at relatively low temperatures.

In another aspect of the invention, a solid delivery system may be utilized to supply the copper precursor, for example, using the ProE-Vap solid delivery and vaporizer unit (commercially available from ATMI, Inc., Danbury, Conn., USA).

The copper precursors of the invention may be packaged in a precursor storage and dispensing package of any suitable type. Depending on the form, e.g., solid or liquid form, of the precursor, preferred precursor storage and dispensing packages include those described in U.S. Provisional Patent Application No. 60/662,515 filed in the names of Paul J. Marganski, et al. for “SYSTEM FOR DELIVERY OF REAGENTS FROM SOLID SOURCES THEREOF” and the storage and dispensing apparatus variously described in U.S. Pat. No. 5,518,528; U.S. Pat. No. 5,704,965; U.S. Pat. No. 5,704,967; U.S. Pat. No. 5,707,424; U.S. Pat. No. 6,101,816; U.S. Pat. No. 6,089,027; U.S. Patent Application Publication 20040206241; U.S. Pat. No. 6,921,062; U.S. patent application Ser. No. 10/858,509; and U.S. patent application Ser. No. 10/022,298, the disclosures of all of which are hereby incorporated herein by reference, in their respective entireties.

A wide variety of CVD, ALD or RVD process conditions may be employed in the use of the precursor compositions of the present invention. Generalized process conditions may include substrate temperature in a range of 150-400° C.; pressure in a range of 0.05-5 Torr; and carrier gas flows of helium, hydrogen, nitrogen, or argon in a range of 25-750 sccm, at a temperature approximately the same as the vaporizer, e.g., in a range of 50 to 120° C.

The deposition of copper thin films with useful electrical properties (low resistivity) and good adhesion to the barrier layer (e.g., formed of TiN or TaN), are also achieved by the process and precursors of the present invention. The conformality of the deposited film is practically achievable through CVD, ALD or RVD techniques that preferably provide a pathway to the achievement of “full-fill” copper metallization. The liquid delivery approach of the present invention, including “flash” vaporization and the use of copper precursor chemistry as herein disclosed, enable next-generation device geometries and dimensions to be attained, e.g., a conformal vertical interconnect of 65 nanometer line width. The conformal deposition of interconnects of these critical dimensions cannot be realized by currently available physical deposition methods. Thus, the approach of the present invention affords a viable pathway to future generation devices, and embodies a substantial advance in the art.

The features and advantages of the invention are more fully shown by the following illustrative and non-limiting examples.

### EXAMPLE 1

### Synthesis of Copper (I) 2-methoxy-1,3-diisopropylamidinate

22.42 g NaOMe (0.42 mol) was added to a solution of 52.40 g ⁱPrN═C═NPrⁱ (0.42 mol) in ˜300 ml Et₂O at 0° C. The reaction mixture was allowed to warm to room temperature during the period of 4 hrs. Then 41.03 g CuCl (0.41 mol) was added to the above solution at 0° C. and the reaction mixture gradually turned yellow. The resulting solution was stirred and warmed to room temperature overnight. All volatiles were removed in vacuo and the solid residue was extracted in ˜500 ml hexane. The resulting yellow filtrate was concentrated in vacuo and 53.00 g copper (I) 2-methoxy-1,3-diisopropylamidinate (CuMOPA, 0.12 mol, 57% yield) was collected after purification. Data for CuMOPA: ¹H NMR (benzene-d₆, 21° C.) δ 3.73 (sep., 1H, —CH(CH₃)₂), 3.33 (s, 3H, CH₃O—), 1.24 (d, 6H, —CH(CH₃)₂). ¹³C NMR (benzene-d₆, 21° C.) δ 167.8 (—COCH₃), 59.3 (—COCH₃), 46.9 (—CH(CH₃)₂), 27.6 (—CH(CH₃)₂). Anal. Calc. for C₁₆H₃₄N₄O₂Cu₂: C, 43.52%; H, 7.76%; N, 12.69%. Found: C, 43.23%; H, 7.97%; N, 12.53%.

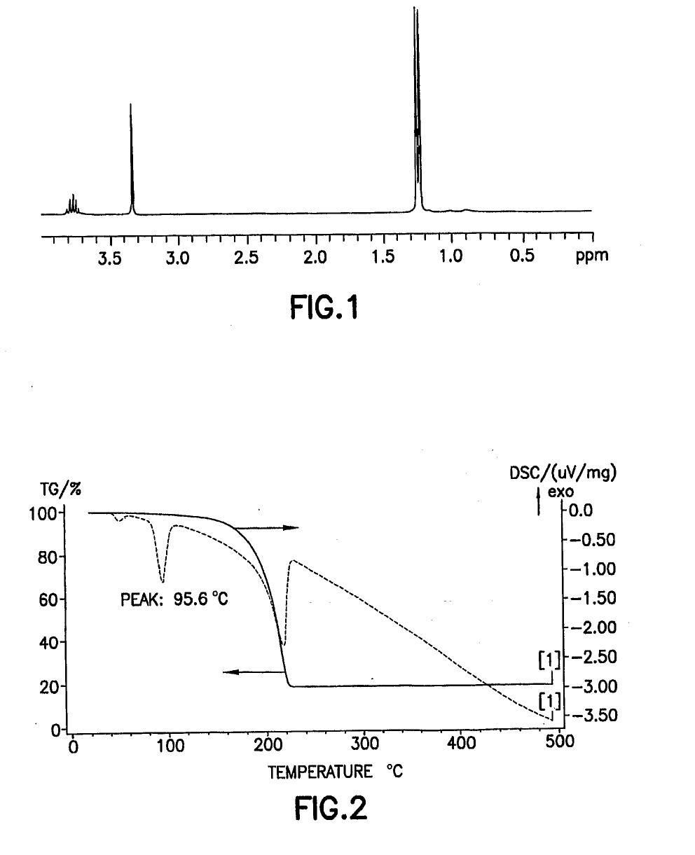

FIG. 1 illustrates the ¹H NMR (benzene-d₆, 21° C.) for CuMOPA, having the following peaks: δ 3.73 (sep., 1H, —CH(CH₃)₂), 3.33 (s, 3H, CH₃O—), 1.24 (d, 6H, —CH(CH₃)₂).

FIG. 2 corresponds to the TGA/DSC plot for a 7.50 mg sample of CuMOPA illustrating the material transportable at temperatures below 200° C. at atmospheric pressure. The melting peak is about 95.9° C. and the residue is about 17%.

FIG. 3 is the ORTEP structure for copper (I) 2-methoxy-1,3-diisopropylamidinate, showing the dimeric structure of the compound and 30% probability thermal ellipsoids. It can be seen that CuMOPA is dinuclear in nature in the solid state.

### EXAMPLE 2

### Synthesis of Copper (I) 2-ethoxy-1,3-diisopropylamidinate

9.97 g NaOEt (0.15 mol) was added to a solution of 18.48 g ⁱPrN═C═NPrⁱ (0.15 mol) in ˜100 ml Et₂O at 0° C. The reaction mixture was allowed to warm to room temperature during the period of 4 hrs. Then 14.50 g CuCl (0.14 mol) was added to the above solution at 0° C. and the reaction mixture gradually turned yellow. The resulting solution was stirred and warmed to room temperature overnight. The volatiles were removed in vacuo and the solid residue was extracted in ˜200 ml hexane. The resulting yellow filtrate was concentrated in vacuo and 18.00 g copper (I) 2-ethoxy-1,3-diisopropylamidinate (CuEOPA, 0.038 mol, 54% yield) was collected after purification.

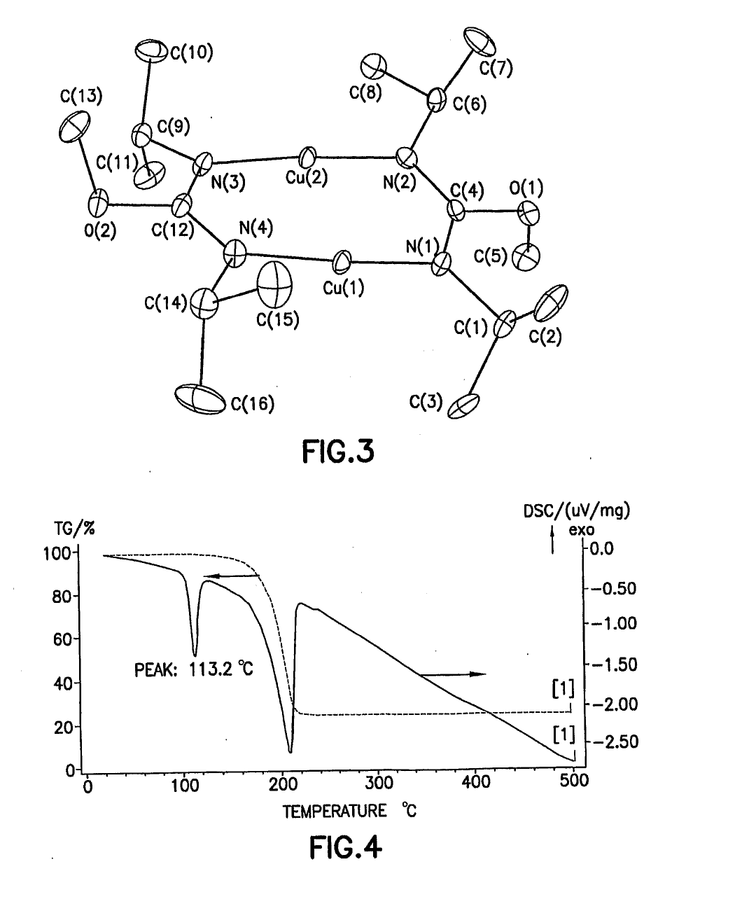

FIG. 4 corresponds to the TGA/DSC plot for a 9.24 mg sample of copper (I) 2-ethoxy-1,3-diisopropylamidinate showing an endothermic melting peak at 113° C. and tie material transportable at temperatures below 210° C. at atmospheric pressure. The melting peak is about 113.2° C. and the residue is about 24%.

### EXAMPLE 3

### Synthesis of Copper (I) 2-t-butoxy-1,3-diisopropylamidinate

12.76 g NaOBu^{t} (0.13 mol) was added to a solution of 16.75 18.48 g ⁱPrN═C═NPrⁱ (0.13 mol) in ˜100 ml Et₂O at 0° C. The reaction mixture was allowed to warm to room temperature during the period of 4 hrs. Then 13.14 g CuCl (0.13 mol) was added to the above solution at 0° C. and the reaction mixture gradually turned yellow. The resulting solution was stirred and warmed to room temperature overnight. The volatiles were removed in vacuo and the solid residue was extracted in ˜200 ml hexane. The resulting yellow filtrate was concentrated in vacuo and 6.32 g copper (I) 2-tert-butoxy-1,3-diisopropylamidinate (CuBOPA, 0.012 mol, 18% yield) was collected after purification.

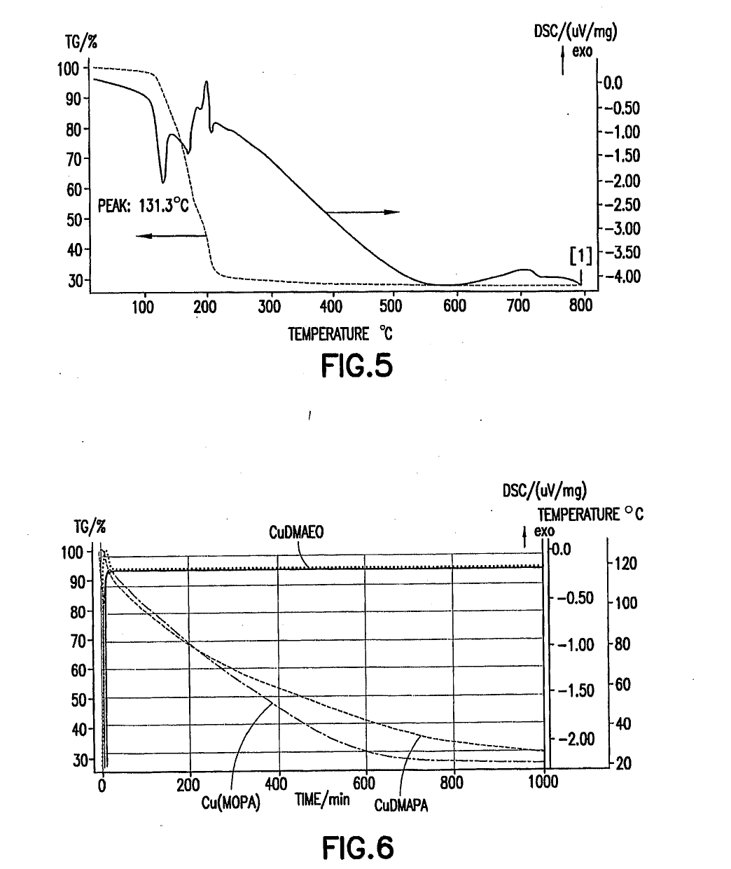

FIG. 5 corresponds to the TGA plot for a 7.84 mg sample of copper (I) 2-t-butoxy-1,3-diisopropylamidinate (CuBOPA). The melting peak is about 131.3° C. and the residue is about 29%. It can be seen that CuBOPA is volatile at transport temperatures below 230° C., and has aresidual mass below 5%.

### EXAMPLE 4

### Isothermal Experiments of CuMOPA, CuDMAPA and Copper (II) Dimethylaminoethoxide (CuDMAEO)

Sublimed CuMOPA (sample size 8.99 mg) and copper (I) 2-dimethylamino-1,3-diisopropylamidinate (CuDMAPA) (8.64 mg) were heated at 120° C. for 1000 minutes in a NETZSCH STA 449c cell and the STA data recorded. It can be seen in FIG. 6 that the CuMOPA displayed a better linear weight loss. Although not wishing to be bound by theory, assuming all the weight loss comes from the transportation instead of decomposition of the precursors, CuMOPA should be the better CVD/ALD precursor to be delivered to the vaporizer.

### EXAMPLE 5

### Stabilization of CuMOPA by HMOPA, and Stabilization of CuDMAPA by HDMAPA

The advantages of the isourea and guanidine solvent/additive compositions of the invention were demonstrated in a stabilization study, in which specific isoureas and guanidines were assessed for their effect on stability of CuMOPA and CuDMAPA, respectively, and unexpectedly found to stabilize such copper complexes for significant periods of time. This is shown by the data in Table 1 below.

TABLE 1

| | Temperature | Time | | |
|---|---|---|---|---|
| | (° C.) | (hours) | NMR | Observation |
| (CuMOPA)₂ | 110 | 356 | <5% | Cu mirror |
| | | | decomposition | |
| (CuMOPA)₂ + | 110 | 356 | <5% | clear |
| HMOPA | | | decomposition | solution |
| | | | | No |
| | | | | precipitation |
| (CuDMAPA)₂ | 110 | 356 | <5% | precipitation |
| | | | decomposition | |
| (CuDMAPA)2 + | 110 | 144 | <5% | clear |
| HDMAPA | | | decomposition | solution |
| | | | | No |
| | | | | precipitation |
| (CuDMAPA)₂ + | 25 | <1 | 100% | precipitation |
| TMG(tetramethyl | | | reacted | |
| guanidine) | | | | |

The foregoing data show that the copper precursor complexes in dimerized form experienced precipitation after extended elevated temperature exposure, with the CuMOPA dimer forming a copper mirror deposit, and the CuDMAPA dimer likewise experiencing precipitation. Contrariwise, and unexpectedly, however, the solution of the CuMOPA dimer in HMOPA, and the solution of the CuDMAPA dimer in HDMAPA, did not undergo any precipitation.

In this respect, it is interesting to note that the CuDMAPA dimer in tetramethyl guanidine after less than one hour at ambient temperature precipitated and underwent complete disproportionation reaction. Such behavior underscores the fact that the solvent species with matching ligands provide a remarkable level of stabilization of the corresponding copper precursor complex against degradation and precipitation, even after long-term exposure to high temperature.

While the invention has been described herein with reference to various specific embodiments, it will be appreciated that the invention is not thus limited, and extends to and encompasses various other modifications and embodiments, as will be appreciated by those ordinarily skilled in the art. Accordingly, the invention is intended to be broadly construed and interpreted, in accordance with the ensuing claims.

1-44. (canceled)

45. A copper precursor composition, comprising a copper precursor selected from the group consisting of compounds of the formulae: 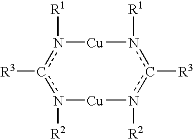
wherein:
R¹, R², and R³ may be the same as or different from one another and each is independently selected from the group consisting of H, linear or branched C₁-C₆ alkyl, C₁-C₆ alkoxy, alkylamino, aryl, silyl and aryloxy groups, with the provision that at least one of R¹, R², and R³ is a C₁-C₆ alkoxy or a aryloxy group.

46. The copper precursor composition of claim 45, wherein the copper precursor comprises:
copper (I) 2-methoxy-1,3-diisopropylamidinate (Copper (I) o-methyl-N,N′-diisopropylisoureate, CuMOPA);
copper (I) 2-ethoxy-1,3-diisopropylamidinate (Copper (I) o-ethyl-N,N′-diisopropylisoureate), or
copper (I) 2-t-butoxy-1,3-diisopropylamidinate (Copper (I) o-tert-Butyl-N,N′-diisopropylisoureate).

47. The copper precursor composition of claim 45, wherein R¹ and R² are isopropyl groups.

48. The copper precursor composition of claim 45, wherein R³ is a C₁-C₆ alkoxy group.

49. The copper precursor composition of claim 45, further comprising at least one organic solvent, wherein said at least one organic solvent comprises a species selected from the group consisting of alkanes, alkenes, alkynes, imines, aryl, amine and amide solvents.

50. The copper precursor composition of claim 45, further comprising at least one organic solvent, wherein said at least one organic solvent comprises a species selected from the group consisting of hexane, heptane, octane, pentane, benzene, toluene, triethylamine, tert-butylamine, imines, N,N′-diisopropylcarbodimide, dimethylformamide, and combinations thereof.

51. A precursor storage and dispensing package, containing a copper precursor selected from the group consisting of:
copper (I) 2-methoxy-1,3-diisopropylamidinate (Copper (I) o-methyl-N,N′-diisopropylisoureate, CuMOPA);
copper (I) 2-ethoxy-1,3-diisopropylamidinate (Copper (I) o-ethyl-N,N′-diisopropylisoureate), and
copper (I) 2-t-butoxy-1,3-diisopropylamidinate (Copper (I) o-tert-Butyl-N,N′-diisopropylisoureate).

52. A copper precursor composition, comprising (i) an organocopper compound or complex, and (ii) one of isoureas of formula (A) and guanidines of formula (B): 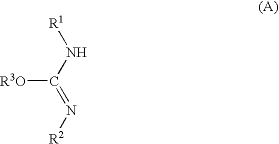
wherein each of R¹, R² and R³ is independently selected from hydrogen, C₁-C₈ alkyl, C₂-C₈ alkenyl, amino, aryl, C₁-C₆ alkylamino, silyl, mono-, bi- and tri-alkylsilyl wherein alkyl is C₁-C₈ alkyl, and cyano (—CN); and 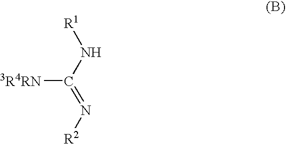
wherein each of R¹, R², R³ and R⁴ is independently selected from hydrogen, C₁-C₈ alkyl, C₂-C₈ alkenyl, amino, aryl, C₁-C₆ alkylamino, silyl, mono-, bi- and tri-alkylsilyl wherein alkyl is C₁-C₈ alkyl, and cyano (—CN).

53. The copper precursor composition of claim 52, selected from the group consisting of:
(a) CuMOPA in HMOPA solution; and
(b) CuDMAPA in HDMAPA solution.

54. A method of stabilizing a copper complex against degradation at elevated temperature, wherein the copper complex is selected from the group consisting of copper amidinates, copper guanidinates, and copper isoureates, said method comprising formulating said copper complex with a corresponding amidinate, guanidinate or isoureate compound.

55. The method of claim 54, wherein the copper complex comprises CuMOPA.

56. The method of claim 54, wherein the copper complex comprises CuDMAPA.

57. The method of claim 54, wherein the copper complex is formulated with HMOPA.

58. The method of claim 54, wherein the copper complex is formulated with HDMAPA.

59. A method of depositing copper on a substrate, comprising contacting the substrate with a vapor of a copper precursor composition of claim 52.

60. The method of claim 59, wherein said contacting comprises chemical vapor deposition.

61. The method of claim 59, wherein said contacting comprises atomic layer deposition.

62. The method of claim 59, wherein the copper precursor composition comprises a copper precursor compound selected from the group consisting of:
copper (I) 2-methoxy-1,3-diisopropylamidinate (Copper (I) o-methyl-N,N′-diisopropylisoureate, CuMOPA);
copper (I) 2-ethoxy-1,3-diisopropylamidinate (Copper (I) o-ethyl-N,N′-diisopropylisoureate), and
copper (I) 2-t-butoxy-1,3-diisopropylamidinate (Copper (I) o-tert-Butyl-N,N′-diisopropylisoureate).
